(19) United States
(12) Patent Application Publication
(10) Pub. No.: US 2016/0056796 A1
(43) Pub. Date: Feb. 25, 2016

(54) INTEGRATED CIRCUITS

(71) Applicant: SK hynix Inc., Icheon-si Gyeonggi-do (KR)

(72) Inventor: Nam Pyo HONG, Cheonan-si Chungcheongnam-do (KR)

(21) Appl. No.: 14/522,764

(22) Filed: Oct. 24, 2014

(30) Foreign Application Priority Data
Aug. 20, 2014 (KR) 10-2014-0108637

(51) Int. Cl. H03K 3/012; H01L 25/065

(52) U.S. Cl. CPC H03K 3/012; H01L 25/0657; H01L 2225/06541

(57) ABSTRACT

An integrated circuit may include a first semiconductor device and a second semiconductor device. The first semiconductor device may compare a first internal voltage signal with a reference voltage signal received from outside the first semiconductor device to control a drive of the first internal voltage signal. The second semiconductor device may compare a second internal voltage signal with the first internal voltage signal controlled by the first semiconductor device to control a drive of the second internal voltage signal.

### CROSS-REFERENCE TO RELATED APPLICATION

The present application claims priority under 35 U.S.C 119(a) to Korean Application No. 10-2014-0108637, filed on Aug. 20, 2014, in the Korean Intellectual Property Office, which is incorporated herein by reference in its entirety as set forth in full.

### BACKGROUND

1. Technical Field

Embodiments of the present disclosure generally relate to integrated circuits.

2. Related Art

Recently, integrated circuits have been developed to improve their performances. For example, each of the integrated circuits has been fabricated to include a plurality of semiconductor devices (also, referred to as semiconductor chips) that are vertically stacked. In semiconductor devices that are vertically stacked, each of the semiconductor devices may have electrodes and through silicon vias (TSVs). The electrodes and TSVs may provide electrical signal paths. The electrical signal paths may provide various internal signals and power signals paths to be transmitted with.

The semiconductor devices may receive a power voltage signal VDD from an external system to generate internal voltage signals used in internal operations thereof. The semiconductor devices may receive a ground voltage signal VSS from an external system to generate internal voltage signals used in internal operations thereof. The internal voltage signals necessary for the internal operations of the semiconductor devices may include a core voltage signal VCORE, a high voltage signal VPP (also, referred to as a boost voltage signal), and a low voltage signal VBB (also, referred to as a back-bias voltage signal). The core voltage signal VCORE may be supplied to a memory core region. The high voltage signal VPP may be used to drive or overdrive word lines. The low voltage signal VBB may be applied to a bulk region (or a substrate) of NMOS transistors in the memory core region.

### SUMMARY

According to an embodiment, an integrated circuit may include a first semiconductor device and a second semiconductor device. The first semiconductor device may compare a first internal voltage signal with a reference voltage signal received from outside the first semiconductor device to control a drive of the first internal voltage signal. The second semiconductor device may compare a second internal voltage signal with the first internal voltage signal controlled by the first semiconductor device to control a drive of the second internal voltage signal.

According to an embodiment, an integrated circuit may include a first semiconductor device, a second semiconductor device and a third semiconductor device. The second semiconductor device may compare a second internal voltage signal with a first internal voltage signal outputted from the first semiconductor device to control a drive of the second internal voltage signal. The third semiconductor device may compare a third internal voltage signal with the second internal voltage signal controlled by the second semiconductor device to control a drive of the third internal voltage signal.

According to an embodiment, an integrated circuit may include a first semiconductor device and a second semiconductor device. The first semiconductor device receives a reference voltage signal through a first electrode and may compare a first internal voltage signal with the reference voltage signal to drive the first internal voltage signal. In addition, the first semiconductor device may output the driven first internal voltage signal through a second electrode, a first through silicon via and a first pad portion. The second semiconductor device may receive the first internal voltage signal driven by the first semiconductor device through a second pad portion electrically coupled to the first pad to apply the first internal voltage signal to a third electrode thereof and may compare a second internal voltage signal with the first internal voltage signal to drive the second internal voltage signal. In addition, the second semiconductor device may output the driven second internal voltage signal through a fourth electrode and a second through silicon via.

### BRIEF DESCRIPTION OF THE DRAWINGS

FIG. 1 is a block diagram illustrating a representation of an integrated circuit according to an embodiment.

FIGS. 2 and 3 are timing diagrams illustrating a representation of the operations of the integrated circuit illustrated in FIG. 1.

FIG. 4 is a block diagram illustrating a representation of an integrated circuit according to an embodiment.

FIGS. 5 and 6 are timing diagrams illustrating a representation of the operations of the integrated circuit illustrated in FIG. 4.

FIG. 7 illustrates a block diagram of an example of a representation of a system employing the integrated circuit in accordance with the embodiments discussed above with relation to FIGS. 1-6.

### DETAILED DESCRIPTION OF THE EMBODIMENTS

Embodiments of the present disclosure will be described hereinafter with reference to the accompanying drawings. However, the embodiments described herein are for illustrative purposes only and are not intended to limit the scope of the present disclosure.

Various embodiments may be directed to integrated circuits including semiconductor devices which are vertically stacked.

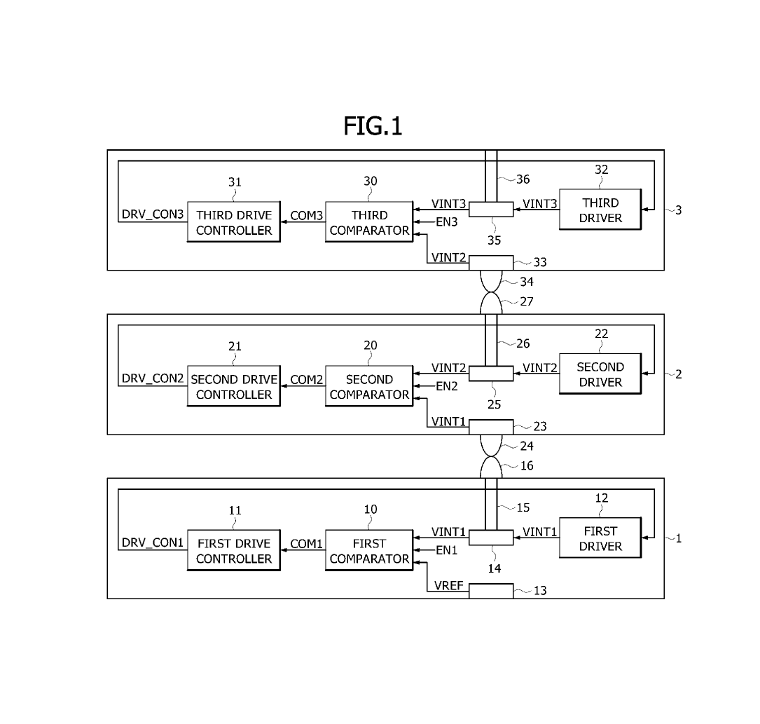

Referring to FIG. 1, an integrated circuit according to an embodiment may include a first semiconductor device 1, a second semiconductor device 2 and a third semiconductor device 3. The first semiconductor device 1 may control a drive/non-drive of a first internal voltage signal VINT1 based on a reference voltage signal VREF. For example, the first semiconductor device 1 may drive the first internal voltage signal VINT1 if the first internal voltage signal VINT1 has a level which is lower than that of the reference voltage signal VREF. The first semiconductor device 1 may not drive the first internal voltage signal VINT1 if, for example, the first internal voltage signal VINT1 has a level which is equal to or higher than that of the reference voltage signal VREF. The second semiconductor device 2 may receive the first internal voltage signal VINT1 from the first semiconductor device 1. The second semiconductor device 2 may control a drive/non-drive of a second internal voltage signal VINT2 based on the first internal voltage signal VINT1. For example, the second semiconductor device 2 may drive the second internal voltage signal VINT2 if the second internal voltage signal VINT2 has a level which is lower than that of the first internal voltage signal VINT1. The second semiconductor device 2 may not drive the second internal voltage signal VINT2 if, for example, the second internal voltage signal VINT2 has a level which is equal to or higher than that of the first internal voltage signal VINT1. The third semiconductor device 3 may receive the second internal voltage signal VINT2 from the second semiconductor device 2. The third semiconductor device 3 may control a drive/non-drive of a third internal voltage signal VINT3 based on the second internal voltage signal VINT2. For example, the third semiconductor device 3 may drive the third internal voltage signal VINT3 if the third internal voltage signal VINT3 has a level which is lower than that of the second internal voltage signal VINT2. The third semiconductor device 3 may not drive the third internal voltage signal VINT3 if, for example, the third internal voltage signal VINT3 has a level which is equal to or higher than that of the second internal voltage signal VINT2.

The first semiconductor device 1 may include a first comparator 10, a first drive controller 11, and a first driver 12. The first semiconductor device 1 may also include a first electrode 13, a second electrode 14, and a first through silicon via 15. The first semiconductor device 1 may include a first pad portion 16. The first and second electrodes 13 and 14 may be, for example, metal electrodes. The first electrode 13 may receive the reference voltage signal VREF from an external device or an external system. The external device or the external system may correspond to, for example but not limited to, a controller (not illustrated) or a test apparatus (not illustrated). The second electrode 14 may receive the first internal voltage signal VINT1 from the first driver 12. The second electrode 14 may output the first internal voltage signal VINT1 to the second semiconductor device 2 through the first through silicon via 15 and the first pad portion 16. The second electrode 14 may apply the first internal voltage signal VINT1 to the first comparator 10. The first through silicon via 15 may be electrically connected or coupled to the second electrode 14. The first pad portion 16 may be electrically connected or coupled to the first through silicon via 15.

The first comparator 10 may compare the first internal voltage signal VINT1 with the reference voltage signal VREF to generate a first comparison signal COM1 while a first enablement signal EN1 is, for example, enabled. A logic level of the first comparison signal COM1 may be determined according to a comparison result of the reference voltage signal VREF and the first internal voltage signal VINT1. For example, the first comparison signal COM1 may be set to have a logic “high” level if a level of the first internal voltage signal VINT1 is lower than a level of the reference voltage signal VREF. The first comparison signal COM1 may be set to have a logic “low” level if, for example, a level of the first internal voltage signal VINT1 is higher than a level of the reference voltage signal VREF. However, the logic levels of the first comparison signal COM1 may be set to be different according to the various embodiments. The first enablement signal EN1 may be generated from initialization signals such as, for example but not limited to, a power-up signal, a reset signal and a mode register set (MRS) signal or from command signals such as a clock enablement signal and a refresh signal. The first enablement signal EN1 may be generated to include a pulse. In such examples, the first enablement signal EN1 may be set to be enabled during a period that corresponds to a width of the pulse thereof.

The first drive controller 11 may generate a first drive control signal DRV_CON1 in response to the first comparison signal COM1. A logic level of the first drive control signal DRV_CON1 may be determined according to a logic level of the first comparison signal COM1. For example, the first drive control signal DRV_CON1 may be generated to have a logic “low” level if the first comparison signal COM1 has a logic “low” level. The first drive control signal DRV_CON1 may be generated to have a logic “high” level if, for example, the first comparison signal COM1 has a logic “high” level. The first drive controller 11 may be realized using a buffer circuit (not illustrated) that buffers the first comparison signal COM1 and outputs the buffered first comparison signal COM1 as the first drive control signal DRV_CON1. In various embodiments, the first semiconductor device 1 may be realized without the first drive controller 11. The first driver 12 may control a drive/non-drive of the first internal voltage signal VINT1 according to a logic level of the first drive control signal DRV_CON1. For example, the first driver 12 may drive the first internal voltage signal VINT1 if the first drive control signal DRV_CON1 has a logic “high” level. The first driver 12 may not drive the first internal voltage signal VINT1 if, for example, the first drive control signal DRV_CON1 has a logic “low” level. In various embodiments, if the first semiconductor device 1 is realized without the first drive controller 11, the first driver 12 may be configured to control a drive/non-drive of the first internal voltage signal VINT1 according to a logic level of the first comparison signal COM1.

The second semiconductor device 2 may include a second comparator 20, a second drive controller 21, and a second driver 22. The second semiconductor device 2 may also include a third electrode 23, a second pad portion 24, and a fourth electrode 25. The second semiconductor device 2 may include a second through silicon via 26 and a third pad portion 27. The third and fourth electrodes 23 and 25 may be, for example, metal electrodes. The third electrode 23 may receive the first internal voltage signal VINT1 from the first semiconductor device 1 through the second pad portion 24 electrically connected or coupled to the first pad portion 16. The fourth electrode 25 may receive the second internal voltage signal VINT2 from the second driver 22. The fourth electrode 25 may output the second internal voltage signal VINT2 to the third semiconductor device 3 through the second through silicon via 26 and the third pad portion 27. The fourth electrode 25 may apply the second internal voltage signal VINT2 to the second comparator 20. The second through silicon via 26 may be electrically connected or coupled to the fourth electrode 25. The third pad portion 27 may be electrically connected or coupled to the second through silicon via 26.

The second comparator 20 may compare the second internal voltage signal VINT2 with the first internal voltage signal VINT1 to generate a second comparison signal COM2 while a second enablement signal EN2 is enabled. A logic level of the second comparison signal COM2 may be determined according to a comparison result of the second internal voltage signal VINT2 and the first internal voltage signal VINT1. For example, the second comparison signal COM2 may be set to have a logic “high” level if a level of the second internal voltage signal VINT2 is lower than a level of the first internal voltage signal VINT1. The second comparison signal COM2 may be set to have a logic “low” level if, for example, a level of the second internal voltage signal VINT2 is higher than a level of the first internal voltage signal VINT1. However, the logic levels of the second comparison signal COM2 may be set to be different according to the various embodiments. The second enablement signal EN2 may be generated from the initialization signals such as, for example but not limited to, a power-up signal, a reset signal and a mode register set (MRS) signal or from the command signals such as a clock enablement signal and a refresh signal. The first and second enablement signals EN1 and EN2 may be generated to be simultaneously enabled, or substantially simultaneously enabled. Alternatively, the second enablement signal EN2 may be generated to be enabled after the first enablement signal EN1 is enabled. The second enablement signal EN2 may be generated to include a pulse. In such examples, the second enablement signal EN2 may be set to be enabled during a period that corresponds to a width of the pulse thereof.

The second drive controller 21 may generate a second drive control signal DRV_CON2 in response to the second comparison signal COM2. A logic level of the second drive control signal DRV_CON2 may be determined according to a logic level of the second comparison signal COM2. For example, the second drive control signal DRV_CON2 may be generated to have a logic “low” level if the second comparison signal COM2 has a logic “low” level. The second drive control signal DRV_CON2 may be generated to have a logic “high” level if, for example, the second comparison signal COM2 has a logic “high” level. The second drive controller 21 may be realized using a buffer circuit (not illustrated) that buffers the second comparison signal COM2 and outputs the buffered second comparison signal COM2 as the second drive control signal DRV_CON2. In various embodiments, the second semiconductor device 2 may be realized without the second drive controller 21. The second driver 22 may control a drive/non-drive of the second internal voltage signal VINT2 according to a logic level of the second drive control signal DRV_CON2. For example, the second driver 22 may drive the second internal voltage signal VINT2 if the second drive control signal DRV_CON2 has a logic “high” level. The second driver 22 may not drive the second internal voltage signal VINT2 if, for example, the second drive control signal DRV_CON2 has a logic “low” level. In various embodiments, if the second semiconductor device 2 is realized without the second drive controller 21, the second driver 22 may be configured to control a drive/non-drive of the second internal voltage signal VINT2 according to a logic level of the second comparison signal COM2.

The third semiconductor device 3 may include a third comparator 30, a third drive controller 31, and a third driver 32. The third semiconductor device 3 may include a fifth electrode 33, a fourth pad portion 34, and a sixth electrode 35. The third semiconductor device 3 may also include a third through silicon via 36. The fifth and sixth electrodes 33 and 35 may be, for example, metal electrodes. The fifth electrode 33 may receive the second internal voltage signal VINT2 from the second semiconductor device 2 through the fourth pad portion 34 electrically connected or coupled to the third pad portion 27. The sixth electrode 35 may receive the third internal voltage signal VINT3 from the third driver 32. The sixth electrode 35 may output the third internal voltage signal VINT3 to the third comparator 30. The third through silicon via 36 may be electrically connected or coupled to the sixth electrode 35.

The third comparator 30 may compare the third internal voltage signal VINT3 with the second internal voltage signal VINT2 to generate a third comparison signal COM3 while a third enablement signal EN3 is enabled. A logic level of the third comparison signal COM3 may be determined according to a comparison result of the third internal voltage signal VINT3 and the second internal voltage signal VINT2. For example, the third comparison signal COM3 may be set to have a logic “high” level if a level of the third internal voltage signal VINT3 is lower than a level of the second internal voltage signal VINT2. The third comparison signal COM3 may be set to have a logic “low” level if a level of the third internal voltage signal VINT3 is higher than a level of the second internal voltage signal VINT2. The logic levels of the third comparison signal COM3 may be set to be different according to the various embodiments. The third enablement signal EN3 may be generated from the initialization signals such as, for example but not limited to, a power-up signal, a reset signal and a mode register set (MRS) signal or from the command signals such as a clock enablement signal and a refresh signal. The first, second and third enablement signals EN1, EN2 and EN3 may be generated to be simultaneously enabled or substantially simultaneously enabled. Alternatively, the first, second and third enablement signals EN1, EN2 and EN3 may be generated to be sequentially enabled. The third enablement signal EN3 may be generated to include a pulse. In such examples, the third enablement signal EN3 may be set to be enabled during a period that corresponds to a width of the pulse thereof.

The third drive controller 31 may generate a third drive control signal DRV_CON3 in response to the third comparison signal COM3. A logic level of the third drive control signal DRV_CON3 may be determined according to a logic level of the third comparison signal COM3. For example, the third drive control signal DRV_CON3 may be generated to have a logic “low” level if the third comparison signal COM3 has a logic “low” level. The third drive control signal DRV_CON3 may be generated to have a logic “high” level if, for example, the third comparison signal COM3 has a logic “high” level. The third drive controller 31 may be realized using a buffer circuit (not illustrated) that buffers the third comparison signal COM3 and outputs the buffered third comparison signal COM3 as the third drive control signal DRV_CON3. In various embodiments, the third semiconductor device 3 may be realized without the third drive controller 31. The third driver 32 may control a drive/non-drive of the third internal voltage signal VINT3 according to a logic level of the third drive control signal DRV_CON3. For example, the third driver 32 may drive the third internal voltage signal VINT3 if the third drive control signal DRV_CON3 has a logic “high” level. The third driver 32 may not drive the third internal voltage signal VINT3 if, for example, the third drive control signal DRV_CON3 has a logic “low” level. In various embodiments, if the third semiconductor device 3 is realized without the third drive controller 31, the third driver 32 may be configured to control a drive/non-drive of the third internal voltage signal VINT3 according to a logic level of the third comparison signal COM3.

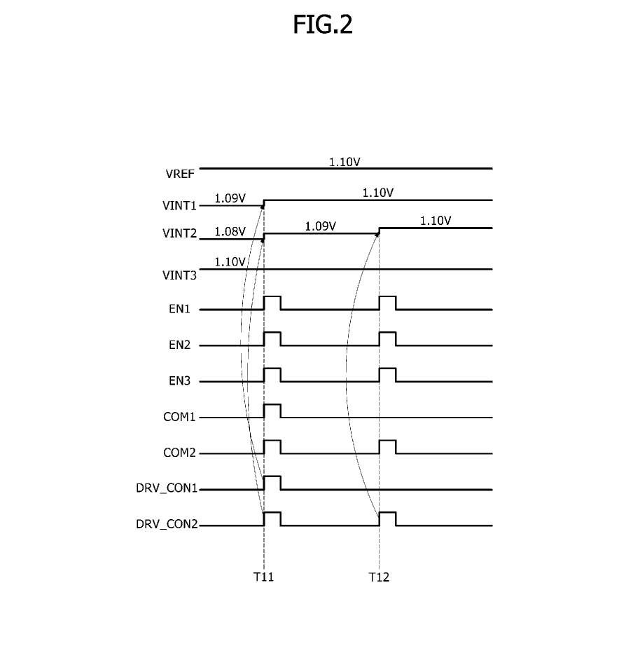

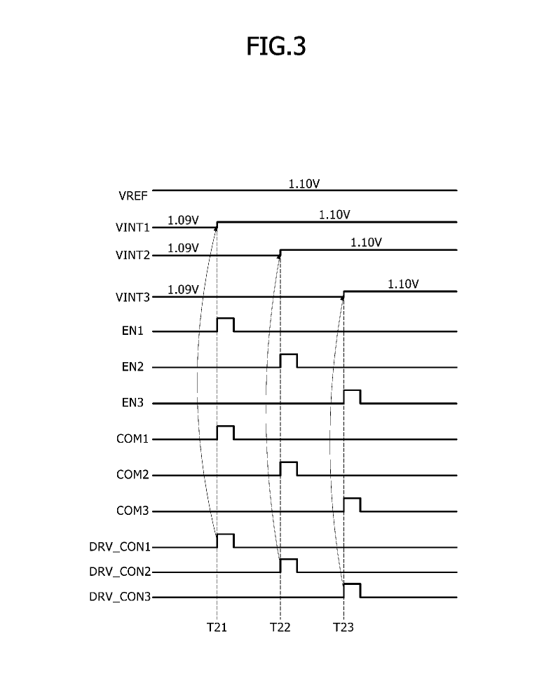

An operation of the integrated circuit having the aforementioned configuration will be described hereinafter with reference to FIGS. 2 and 3 in conjunction with an example in which the first, second and third enablement signals EN1, EN2 and EN3 are simultaneously enabled and an example in which the first, second and third enablement signals EN1, EN2 and EN3 are sequentially enabled.

First, an operation of the integrated circuit will be described with reference to FIG. 2 in conjunction with an example in which the reference voltage signal VREF having a voltage level of 1.10 volts is inputted to the first semiconductor device 1 when the first, second and third internal voltage signals VINT1, VINT2 and VINT3 are set to have 1.09 volts, 1.08 volts and 1.10 volts, respectively.

At a point of time “T11”, if the pulses of the first, second and third enablement signals EN1, EN2 and EN3 are simultaneously applied to the first, second and third comparators 10, 20 and 30, respectively, the first comparison signal COM1 may be generated to have a logic “high” level because a voltage level of the first internal voltage signal VINT1 is lower than a voltage level of the reference voltage signal VREF. In addition, the second comparison signal COM2 may be generated to have a logic “high” level because a voltage level of the second internal voltage signal VINT2 is lower than a voltage level of the first internal voltage signal VINT1. The first and second drive control signals DRV_CON1 and DRV_CON2 may be generated to have a logic “high” level because the first and second comparison signals COM1 and COM2 have a logic “high” level. Accordingly, the first internal voltage signal VINT1 may be driven to have a voltage level of 1.10 volts and the second internal voltage signal VINT2 may be driven to have a voltage level of 1.09 volts.

At a point of time “T12”, if the pulses of the first, second and third enablement signals EN1, EN2 and EN3 are simultaneously applied to the first, second and third comparators 10, 20 and 30, respectively, the second comparison signal COM2 may be generated to have a logic “high” level because a voltage level of the second internal voltage signal VINT2 is lower than a voltage level of the first internal voltage signal VINT1. The second drive control signal DRV_CON2 may be generated to have a logic “high” level because the second comparison signal COM2 has a logic “high” level. Accordingly, the second internal voltage signal VINT2 may be driven to have a voltage level of 1.10 volts.

Next, an operation of the integrated circuit will be described with reference to FIG. 3 in conjunction with an example in which the reference voltage signal VREF having a voltage level of 1.10 volts is inputted to the first semiconductor device 1 when all of the first, second and third internal voltage signals VINT1, VINT2 and VINT3 are set to have 1.09 volts.

At a point of time “T21”, if the pulse of the first enablement signals EN1 is applied to the first comparator 10, the first comparison signal COM1 and the first drive control signal DRV_CON1 may be generated to have a logic “high” level because a voltage level of the first internal voltage signal VINT1 is lower than a voltage level of the reference voltage signal VREF. Thus, the first internal voltage signal VINT1 may be driven to have a voltage level of 1.10 volts which is equal to a voltage level of the reference voltage signal VREF.

At a point of time “T22”, if the pulse of the second enablement signals EN2 is applied to the second comparator 20, the second comparison signal COM2 and the second drive control signal DRV_CON2 may be generated to have a logic “high” level because a voltage level of the second internal voltage signal VINT2 is lower than a voltage level of the first internal voltage signal VINT1. Thus, the second internal voltage signal VINT2 may be driven to have a voltage level of 1.10 volts which is equal to a voltage level of the first internal voltage signal VINT1.

At a point of time “T23”, if the pulse of the third enablement signals EN3 is applied to the third comparator 30, the third comparison signal COM3 and the third drive control signal DRV_CON3 may be generated to have a logic “high” level because a voltage level of the third internal voltage signal VINT3 is lower than a voltage level of the second internal voltage signal VINT2. Thus, the third internal voltage signal VINT3 may be driven to have a voltage level of 1.10 volts which is equal to a voltage level of the second internal voltage signal VINT2.

As described above, according to the integrated circuit illustrated in FIG. 1, the first internal voltage signal VINT1 generated from the first semiconductor device 1 may be driven to have a voltage level which is equal to a voltage level of the reference voltage signal VREF. The second internal voltage signal VINT2 generated from the second semiconductor device 2 may be driven to have a voltage level which is equal to a voltage level of the first internal voltage signal VINT1. Also, the third internal voltage signal VINT3 generated from the third semiconductor device 3 may be driven to have a voltage level which is equal to a voltage level of the second internal voltage signal VINT2. The first internal voltage signal VINT1 generated from the first semiconductor device 1 may be transmitted to the second semiconductor device 2 and may be used to drive the second internal voltage signal VINT2. The second internal voltage signal VINT2 generated from the second semiconductor device 2 may be transmitted to the third semiconductor device 3 and may be used to drive the third internal voltage signal VINT3. Thus, the first, second and third internal voltage signals VINT1, VINT2 and VINT3 outputted from the first, second and third semiconductor devices 1, 2 and 3, which are sequentially stacked, may be stably generated to have the same voltage level.

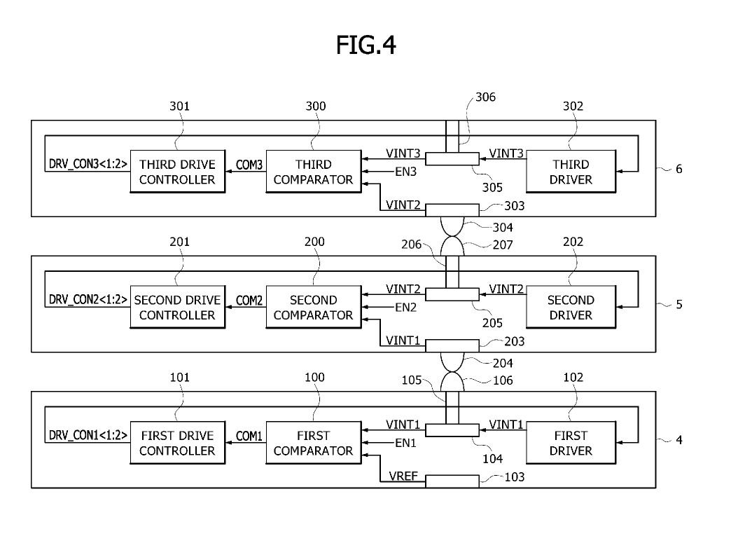

Referring to FIG. 4, an integrated circuit according to an embodiment may include a first semiconductor device 4, a second semiconductor device 5 and a third semiconductor device 6. The first semiconductor device 4 may control a drive of a first internal voltage signal VINT1 based on a reference voltage signal VREF. For example, the first semiconductor device 4 may drive the first internal voltage signal VINT1 to increase a level of the first internal voltage signal VINT1 if the first internal voltage signal VINT1 has a level which is lower than that of the reference voltage signal VREF. The first semiconductor device 4 may drive the first internal voltage signal VINT1 to decrease a level of the first internal voltage signal VINT1 if, for example, the first internal voltage signal VINT1 has a level which is higher than that of the reference voltage signal VREF. The second semiconductor device 5 may receive the first internal voltage signal VINT1 from the first semiconductor device 1. The second semiconductor device 5 may control a drive of a second internal voltage signal VINT2 based on the first internal voltage signal VINT1. For example, the second semiconductor device 5 may drive the second internal voltage signal VINT2 to increase a level of the second internal voltage signal VINT2 if the second internal voltage signal VINT2 has a level which is lower than that of the first internal voltage signal VINT1. The second semiconductor device 5 may drive the second internal voltage signal VINT2 to decrease a level of the second internal voltage signal VINT2 if, for example, the second internal voltage signal VINT2 has a level which is higher than that of the first internal voltage signal VINT1. The third semiconductor device 6 may receive the second internal voltage signal VINT2 from the second semiconductor device 2. The third semiconductor device 6 may control a drive of a third internal voltage signal VINT3 based on the second internal voltage signal VINT2. For example, the third semiconductor device 6 may drive the third internal voltage signal VINT3 to increase a level of the third internal voltage signal VINT3 if the third internal voltage signal VINT3 has a level which is lower than that of the second internal voltage signal VINT2. The third semiconductor device 6 may drive the third internal voltage signal VINT3 to decrease a level of the third internal voltage signal VINT3 if, for example, the third internal voltage signal VINT3 has a level which is higher than that of the second internal voltage signal VINT2.

The first semiconductor device 4 may include a first comparator 100, a first drive controller 101, and a first driver 102. The first semiconductor device 4 may include a first electrode 103, a second electrode 104, and a first through silicon via 105. The first semiconductor device 4 may also include a first pad portion 106. The first and second electrodes 103 and 104 may be, for example, metal electrodes. The first electrode 103 may receive the reference voltage signal VREF from an external device or an external system. The external device or the external system may correspond to, for example but not limited to, a controller (not illustrated) or a test apparatus (not illustrated). The second electrode 104 may receive the first internal voltage signal VINT1 from the first driver 102. The second electrode 104 may output the first internal voltage signal VINT1 to the second semiconductor device 5 through the first through silicon via 105 and the first pad portion 106. The second electrode 104 may apply the first internal voltage signal VINT1 to the first comparator 100. The first through silicon via 105 may be electrically connected or coupled to the second electrode 104. The first pad portion 106 may be electrically connected or coupled to the first through silicon via 105.

The first comparator 100 may compare the first internal voltage signal VINT1 with the reference voltage signal VREF to generate a first comparison signal COM1 while a first enablement signal EN1 is enabled. A logic level of the first comparison signal COM1 may be determined according to a comparison result of the reference voltage signal VREF and the first internal voltage signal VINT1. For example, the first comparison signal COM1 may be set to have a logic “high” level if a level of the first internal voltage signal VINT1 is lower than a level of the reference voltage signal VREF. The first comparison signal COM1 may be set to have a logic “low” level if a level of the first internal voltage signal VINT1 is higher than a level of the reference voltage signal VREF. The logic levels of the first comparison signal COM1 may be set to be different according to the various embodiments. The first enablement signal EN1 may be generated from initialization signals such as, for example but not limited to, a power-up signal, a reset signal and a mode register set (MRS) signal or from command signals such as a clock enablement signal and a refresh signal. The first enablement signal EN1 may be generated to include a pulse. In such examples, the first enablement signal EN1 may be set to be enabled during a period that corresponds to a width of the pulse thereof. While the first enablement signal EN1 is disabled, the first comparison signal COM1 may have a mid-level between a logic “high” level and a logic “low” level.

The first drive controller 101 may generate a first drive control signal DRV_CON1<1:2> in response to the first comparison signal COM1. A logic level combination of the first drive control signal DRV_CON1<1:2> may be determined according to a logic level of the first comparison signal COM1. For example, the first drive control signal DRV_CON1<1:2> may be set to have a logic level combination of “L,H” if the first comparison signal COM1 has a logic “high” level and may be set to have a logic level combination of “H,L” if the first comparison signal COM1 has a logic “low” level. The logic level combination of “L,H” means that a second bit DRV_CON1<2> of the first drive control signal DRV_CON1<1:2> has a logic “low” level and a first bit DRV_CON1<1> of the first drive control signal DRV_CON1<1:2> has a logic “high” level. The number of bits used for the first drive control signal DRV_CON1<1:2> and the logic level combination of the first drive control signal DRV_CON1<1:2> may be set differently (having more or less) according to the various embodiments.

The first driver 102 may control a drive of the first internal voltage signal VINT1 according to a logic level combination of the first drive control signal DRV_CON1<1:2>. For example, the first driver 102 may drive the first internal voltage signal VINT1 to increase a level of the first internal voltage signal VINT1 if the first drive control signal DRV_CON1<1:2> has a logic level combination of “L,H”. The first driver 102 may drive the first internal voltage signal VINT1 to decrease a level of the first internal voltage signal VINT1 if, for example, the first drive control signal DRV_CON1<1:2> has a logic level combination of “H,L”.

The second semiconductor device 5 may include a second comparator 200, a second drive controller 201, and a second driver 202. The second semiconductor device 5 may include a third electrode 203, a second pad portion 204, and a fourth electrode 205. The second semiconductor device 5 may also include a second through silicon via 206 and a third pad portion 207. The third and fourth electrodes 203 and 205 may be, for example, metal electrodes. The third electrode 203 may receive the first internal voltage signal VINT1 from the first semiconductor device 4 through the second pad portion 204 electrically connected or coupled to the first pad portion 106. The fourth electrode 205 may receive the second internal voltage signal VINT2 from the second driver 202 and may output the second internal voltage signal VINT2 to the third semiconductor device 6 through the second through silicon via 206 and the third pad portion 207. The fourth electrode 205 may apply the second internal voltage signal VINT2 to the second comparator 200. The second through silicon via 206 may be electrically connected or coupled to the fourth electrode 205. The third pad portion 207 may be electrically connected or coupled to the second through silicon via 206.

The second comparator 200 may compare the second internal voltage signal VINT2 with the first internal voltage signal VINT1 to generate a second comparison signal COM2 while a second enablement signal EN2 is enabled. A logic level of the second comparison signal COM2 may be determined according to a comparison result of the second internal voltage signal VINT2 and the first internal voltage signal VINT1. For example, the second comparison signal COM2 may be set to have a logic “high” level if a level of the second internal voltage signal VINT2 is lower than a level of the first internal voltage signal VINT1. The second comparison signal COM2 may be set to have a logic “low” level if a level of the second internal voltage signal VINT2 is higher than a level of the first internal voltage signal VINT1. However, the logic levels of the second comparison signal COM2 may be set to be different according to the various embodiments. The second enablement signal EN2 may be generated from the initialization signals such as, for example but not limited to, a power-up signal, a reset signal and a mode register set (MRS) signal or from the command signals such as a clock enablement signal and a refresh signal. The first and second enablement signals EN1 and EN2 may be generated to be simultaneously enabled. Alternatively, the second enablement signal EN2 may be generated to be enabled after the first enablement signal EN1 is enabled. The second enablement signal EN2 may be generated to include a pulse. In such examples, the second enablement signal EN2 may be set to be enabled during a period that corresponds to a width of the pulse thereof. While the second enablement signal EN2 is disabled, the second comparison signal COM2 may have a mid-level between a logic “high” level and a logic “low” level.

The second drive controller 201 may generate a second drive control signal DRV_CON2<1:2> in response to the second comparison signal COM2. A logic level combination of the second drive control signal DRV_CON2<1:2> may be determined according to a logic level of the second comparison signal COM2. For example, the second drive control signal DRV_CON2<1:2> may be set to have a logic level combination of “L,H” if the second comparison signal COM2 has a logic “high” level. The second drive control signal DRV_CON2<1:2> may be set to have a logic level combination of “H,L” if, for example, the second comparison signal COM2 has a logic “low” level. The logic level combination of “L,H” means that a second bit DRV_CON2<2> of the second drive control signal DRV_CON2<1:2> has a logic “low” level and a first bit DRV_CON2<1> of the second drive control signal DRV_CON2<1:2> has a logic “high” level. The number of bits used for the second drive control signal DRV_CON2<1:2> and the logic level combination of the second drive control signal DRV_CON2<1:2> may be set differently (having more or less) according to the various embodiments.

The second driver 202 may control a drive of the second internal voltage signal VINT2 according to a logic level combination of the second drive control signal DRV_CON2<1:2>. For example, the second driver 202 may drive the second internal voltage signal VINT2 to increase a level of the second internal voltage signal VINT2 if the second drive control signal DRV_CON2<1:2> has a logic level combination of “L,H”. The second driver 202 may drive the second internal voltage signal VINT2 to decrease a level of the second internal voltage signal VINT2 if, for example, the second drive control signal DRV_CON2<1:2> has a logic level combination of “H,L”.

The third semiconductor device 6 may include a third comparator 300, a third drive controller 301, and a third driver 302. The third semiconductor device 6 may include a fifth electrode 303, a fourth pad portion 304, and a sixth electrode 305. The third semiconductor device 6 may include a third through silicon via 306. The fifth and sixth electrodes 303 and 305 may be, for example, metal electrodes. The fifth electrode 303 may receive the second internal voltage signal VINT2 from the second semiconductor device 5 through the fourth pad portion 304 electrically connected or coupled to the third pad portion 207. The sixth electrode 305 may receive the third internal voltage signal VINT3 from the third driver 302. The sixth electrode 305 may output the third internal voltage signal VINT3 to the third comparator 300. The third through silicon via 306 may be electrically connected or coupled to the sixth electrode 305.

The third comparator 300 may compare the third internal voltage signal VINT3 with the second internal voltage signal VINT2 to generate a third comparison signal COM3 while a third enablement signal EN3 is enabled. A logic level of the third comparison signal COM3 may be determined according to a comparison result of the third internal voltage signal VINT3 and the second internal voltage signal VINT2. For example, the third comparison signal COM3 may be set to have a logic “high” level if a level of the third internal voltage signal VINT3 is lower than a level of the second internal voltage signal VINT2. The third comparison signal COM3 may be set to have a logic “low” level if a level of the third internal voltage signal VINT3 is higher than a level of the second internal voltage signal VINT2. However, the logic levels of the third comparison signal COM3 may be set to be different according to the various embodiments. The third enablement signal EN3 may be generated from the initialization signals such as, for example but not limited to, a power-up signal, a reset signal and a mode register set (MRS) signal or from the command signals such as a clock enablement signal and a refresh signal. The first, second and the third enablement signals EN1, EN2 and EN3 may be generated to be simultaneously enabled. Alternatively, the first, second and third enablement signals EN1, EN2 and EN3 may be generated to be sequentially enabled. The third enablement signal EN3 may be generated to include a pulse. In such examples, the third enablement signal EN3 may be set to be enabled during a period that corresponds to a width of the pulse thereof. While the third enablement signal EN3 is disabled, the third comparison signal COM3 may have a mid-level between a logic “high” level and a logic “low” level.

The third drive controller 301 may generate a third drive control signal DRV_CON3<1:2> in response to the third comparison signal COM3. A logic level combination of the third drive control signal DRV_CON3<1:2> may be determined according to a logic level of the third comparison signal COM3. For example, the third drive control signal DRV_CON3<1:2> may be set to have a logic level combination of “L,H” if the third comparison signal COM3 has a logic “high” level. The third drive control signal DRV_CON3<1:2> may be set to have a logic level combination of “H,L” if, for example, the third comparison signal COM3 has a logic “low” level. The logic level combination of “L,H” means that a second bit DRV_CON3<2> of the third drive control signal DRV_CON3<1:2> has a logic “low” level and a first bit DRV_CON3<1> of the third drive control signal DRV_CON3<1:2> has a logic “high” level. The number of bits used for the third drive control signal DRV_CON3<1:2> and the logic level combination of the third drive control signal DRV_CON3<1:2> may be set differently (having more or less) according to the various embodiments.

The third driver 302 may control a drive of the third internal voltage signal VINT3 according to a logic level combination of the third drive control signal DRV_CON3<1:2>. For example, the third driver 302 may drive the third internal voltage signal VINT3 to increase a level of the third internal voltage signal VINT3 if the third drive control signal DRV_CON3<1:2> has a logic level combination of “L,H”. The third driver 302 may drive the third internal voltage signal VINT3 to decrease a level of the third internal voltage signal VINT3 if, for example, the third drive control signal DRV_CON3<1:2> has a logic level combination of “H,L”.

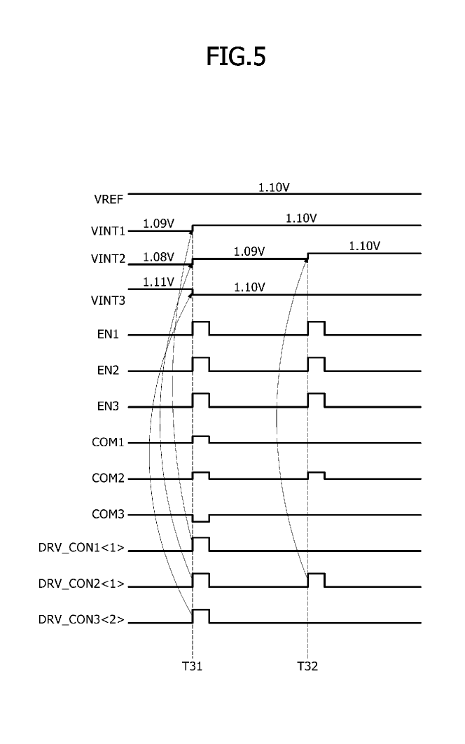

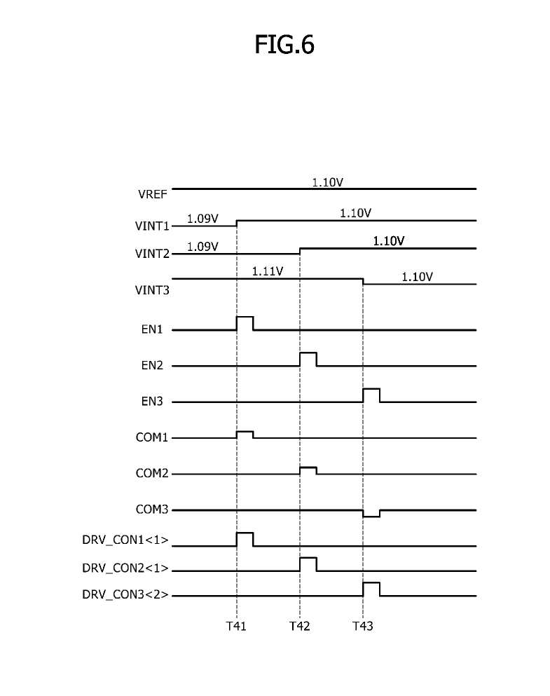

An operation of the integrated circuit having the aforementioned configuration will be described hereinafter with reference to FIGS. 5 and 6 in conjunction with an example in which the first, second and third enablement signals EN1, EN2 and EN3 are simultaneously enabled and an example in which the first, second and third enablement signals EN1, EN2 and EN3 are sequentially enabled.

First, an operation of the integrated circuit of FIG. 4 will be described with reference to FIG. 5 in conjunction with an example in which the reference voltage signal VREF having a voltage level of 1.10 volts is inputted to the first semiconductor device 4 when the first, second and third internal voltage signals VINT1, VINT2 and VINT3 are set to have 1.09 volts, 1.08 volts and 1.11 volts, respectively.

At a point of time “T31”, if the pulses of the first, second and third enablement signals EN1, EN2 and EN3 are simultaneously applied to the first, second and third comparators 100, 200 and 300, respectively, the first comparison signal COM1 may be generated to have a logic “high” level because a voltage level of the first internal voltage signal VINT1 is lower than a voltage level of the reference voltage signal VREF. In addition, the second comparison signal COM2 may be generated to have a logic “high” level because a voltage level of the second internal voltage signal VINT2 is lower than a voltage level of the first internal voltage signal VINT1. Meanwhile, since a voltage level of the third internal voltage signal VINT3 is higher than a voltage level of the second internal voltage signal VINT2, the third comparison signal COM3 may be generated to have a logic “low” level. Since the first comparison signal COM1 has a logic “high” level, only a first bit DRV_CON1<1> of the first drive control signal DRV_CON1<1:2> may be generated to have a logic “high” level. Thus, the first internal voltage signal VINT1 may be increasingly driven to have a voltage level of 1.10 volts. Moreover, since the second comparison signal COM2 has a logic “high” level, only a first bit DRV_CON2<1> of the second drive control signal DRV_CON2<1:2> may be generated to have a logic “high” level. Thus, the second internal voltage signal VINT2 may also be increasingly driven to have a voltage level of 1.09 volts. Additionally, since the third comparison signal COM3 has a logic “low” level, only a second bit DRV_CON3<2> of the third drive control signal DRV_CON3<1:2> may be generated to have a logic “high” level. Thus, the third internal voltage signal VINT3 may be decreasingly driven to have a voltage level of 1.10 volts.

At a point of time “T32”, if the pulses of the first, second and third enablement signals EN1, EN2 and EN3 are simultaneously applied to the first, second and third comparators 100, 200 and 300, respectively, the second comparison signal COM2 may be generated to have a logic “high” level because a voltage level of the second internal voltage signal VINT2 is lower than a voltage level of the first internal voltage signal VINT1. Since the second comparison signal COM2 has a logic “high” level, only a first bit DRV_CON2<1> of the second drive control signal DRV_CON2<1:2> may be generated to have a logic “high” level. Thus, the second internal voltage signal VINT2 may be increasingly driven to have a voltage level of 1.10 volts.

Next, an operation of the integrated circuit of FIG. 4 will be described with reference to FIG. 6 in conjunction with an example in which the reference voltage signal VREF having a voltage level of 1.10 volts is inputted to the first semiconductor device 4 when the first and second internal voltage signals VINT1 and VINT2 are set to have 1.09 volts and the third internal voltage signal VINT3 is set to have 1.11 volts.

At a point of time “T41”, if the pulse of the first enablement signals EN1 is applied to the first comparator 100, the first comparison signal COM1 may be generated to have a logic “high” level and only a first bit DRV_CON1<1> of the first drive control signal DRV_CON1<1:2> may be generated to have a logic “high” level because a voltage level of the first internal voltage signal VINT1 is lower than a voltage level of the reference voltage signal VREF. Thus, the first internal voltage signal VINT1 may be increasingly driven to have a voltage level of 1.10 volts which is equal to a voltage level of the reference voltage signal VREF.

At a point of time “T42”, if the pulse of the second enablement signals EN2 is applied to the second comparator 200, the second comparison signal COM2 may be generated to have a logic “high” level and only a first bit DRV_CON2<1> of the second drive control signal DRV_CON2<1:2> may be generated to have a logic “high” level because a voltage level of the second internal voltage signal VINT2 is lower than a voltage level of the first internal voltage signal VINT1. Thus, the second internal voltage signal VINT2 may be increasingly driven to have a voltage level of 1.10 volts which is equal to a voltage level of the first internal voltage signal VINT1.

At a point of time “T43”, if the pulse of the third enablement signals EN3 is applied to the third comparator 300, the third comparison signal COM3 may be generated to have a logic “low” level and only a second bit DRV_CON3<2> of the third drive control signal DRV_CON3<1:2> may be generated to have a logic “high” level because a voltage level of the third internal voltage signal VINT3 is higher than a voltage level of the second internal voltage signal VINT2. Thus, the third internal voltage signal VINT3 may be decreasingly driven to have a voltage level of 1.10 volts which is equal to a voltage level of the second internal voltage signal VINT2.

As described above, according to the integrated circuit illustrated in FIG. 4, the first internal voltage signal VINT1 generated from the first semiconductor device 4 may be driven to have a voltage level which is equal to a voltage level of the reference voltage signal VREF. The second internal voltage signal VINT2 generated from the second semiconductor device 5 may be driven to have a voltage level which is equal to a voltage level of the first internal voltage signal VINT1. The third internal voltage signal VINT3 generated from the third semiconductor device 6 may be driven to have a voltage level which is equal to a voltage level of the second internal voltage signal VINT2. The first internal voltage signal VINT1 generated from the first semiconductor device 4 may be transmitted to the second semiconductor device 5 and may be used to drive the second internal voltage signal VINT2. The second internal voltage signal VINT2 generated from the second semiconductor device 5 may be transmitted to the third semiconductor device 6 and may be used to drive the third internal voltage signal VINT3. Thus, the first, second and third internal voltage signals VINT1, VINT2 and VINT3 outputted from the first, second and third semiconductor devices 4, 5 and 6, which are sequentially stacked, may be stably generated to have the same voltage level.

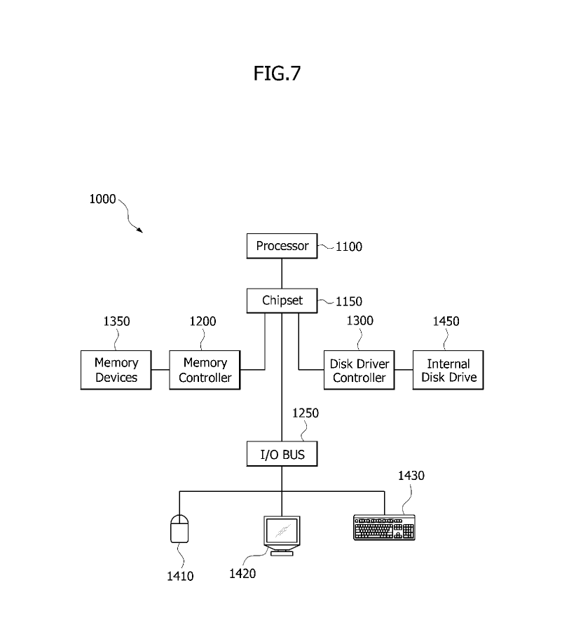

The integrated circuit discussed above (see FIGS. 1-6) are particular useful in the design of memory devices, processors, and computer systems. For example, referring to FIG. 7, a block diagram of a system employing the integrated circuit in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one integrated circuit as discussed above with reference to FIGS. 1-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one integrated circuit as discussed above with relation to FIGS. 1-6, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 7 is merely one example of a system employing the integrated circuit as discussed above with relation to FIGS. 1-6. In alternate embodiments, such as cellular phones or digital cameras, the components may differ from the embodiments illustrated in FIG. 7.

While various embodiments have been described above, it will be understood to those skilled in the art that the embodiments described are by way of example only. Accordingly, the refresh circuit described herein should not be limited based on the described embodiments.

What is claimed is:

1. An integrated circuit comprising:
a first semiconductor device suitable for comparing a first internal voltage signal with a reference voltage signal received from outside the first semiconductor device to control a drive of the first internal voltage signal; and
a second semiconductor device suitable for comparing a second internal voltage signal with the first internal voltage signal controlled by the first semiconductor device to control a drive of the second internal voltage signal.

2. The integrated circuit of claim 1, wherein the first internal voltage signal is transmitted from the first semiconductor device to the second semiconductor device through at least one of an electrode, a through silicon via and a pad.

3. The integrated circuit of claim 1, wherein the first semiconductor device includes:
a first electrode suitable for receiving the reference voltage signal;
a second electrode suitable for receiving the first internal voltage signal;
a first through silicon via electrically coupled to the second electrode; and
a first pad electrically coupled to the first through silicon via.

4. The integrated circuit of claim 3, wherein the first semiconductor device further includes:
a first comparator suitable for comparing the first internal voltage signal with the reference voltage signal to generate a first comparison signal; and
a first driver suitable for driving the first internal voltage signal in response to the first comparison signal.

5. The integrated circuit of claim 4, wherein the first driver drives the first internal voltage signal or stops a drive of the first internal voltage signal, in response to the first comparison signal.

6. The integrated circuit of claim 4, wherein the first driver drives the first internal voltage signal to increase or decrease a level of the first internal voltage signal, in response to the first comparison signal.

7. The integrated circuit of claim 3, wherein the second semiconductor device includes:
a second pad electrically coupled to the first pad;
a third electrode electrically coupled to the second pad and suitable for receiving the first internal voltage signal;
a fourth electrode suitable for receiving the second internal voltage signal;
a second through silicon via electrically coupled to the fourth electrode; and
a third pad electrically coupled to the second through silicon via.

8. The integrated circuit of claim 7, wherein the second semiconductor device further includes:
a second comparator suitable for comparing the second internal voltage signal with the first internal voltage signal to generate a second comparison signal; and
a second driver suitable for driving the second internal voltage signal in response to the second comparison signal.

9. The integrated circuit of claim 7, further comprising a third semiconductor device suitable for comparing a third internal voltage signal with the second internal voltage signal controlled by the second semiconductor device to control a drive of the third internal voltage signal.

10. The integrated circuit of claim 9, wherein the third semiconductor device includes:
a fourth pad electrically coupled to the third pad;
a fifth electrode electrically coupled to the second pad and suitable for receiving the second internal voltage signal;
a sixth electrode suitable for receiving the third internal voltage signal;
a third through silicon via electrically coupled to the sixth electrode.

11. The integrated circuit of claim 10, wherein the third semiconductor device further includes:
a third comparator suitable for comparing the third internal voltage signal with the second internal voltage signal to generate a third comparison signal; and
a third driver suitable for driving the third internal voltage signal in response to the third comparison signal.

12. An integrated circuit comprising:
a first semiconductor device suitable for outputting a first internal voltage signal;
a second semiconductor device suitable for comparing a second internal voltage signal with the first internal voltage signal outputted from the first semiconductor device to control a drive of the second internal voltage signal; and
a third semiconductor device suitable for comparing a third internal voltage signal with the second internal voltage signal controlled by the second semiconductor device to control a drive of the third internal voltage signal.

13. The integrated circuit of claim 12, wherein the second internal voltage signal is transmitted from the second semiconductor device to the third semiconductor device through at least one of an electrode, a through silicon via and a pad.

14. The integrated circuit of claim 13, wherein the second semiconductor device includes:
a first electrode suitable for receiving the first internal voltage signal;
a second electrode suitable for receiving the second internal voltage signal;
a first through silicon via electrically coupled to the second electrode; and
a first pad electrically coupled to the first through silicon via.

15. The integrated circuit of claim 14, wherein the second semiconductor device further includes:
a first comparator suitable for comparing the second internal voltage signal with the first internal voltage signal to generate a first comparison signal; and
a first driver suitable for driving the second internal voltage signal in response to the first comparison signal.

16. The integrated circuit of claim 15, wherein the first driver drives the first internal voltage signal or stops a drive of the first internal voltage signal, in response to the first comparison signal.

17. The integrated circuit of claim 15, wherein the first driver drives the second internal voltage signal to increase or decrease a level of the second internal voltage signal, in response to the first comparison signal.

18. The integrated circuit of claim 14, wherein the third semiconductor device includes:
a second pad electrically coupled to the first pad;
a third electrode electrically coupled to the second pad and suitable for receiving the second internal voltage signal;
a fourth electrode suitable for receiving the third internal voltage signal;
a second through silicon via electrically coupled to the fourth electrode; and
a third pad electrically coupled to the second through silicon via.

19. The integrated circuit of claim 18, wherein the third semiconductor device further includes:
a second comparator suitable for comparing the third internal voltage signal with the second internal voltage signal to generate a second comparison signal; and
a second driver suitable for driving the third internal voltage signal in response to the second comparison signal.

20. An integrated circuit comprising:
a first semiconductor device suitable for receiving a reference voltage signal through a first electrode, suitable for comparing a first internal voltage signal with the reference voltage signal to drive the first internal voltage signal, and suitable for outputting the driven first internal voltage signal through a second electrode, a first through silicon via and a first pad portion; and
a second semiconductor device suitable for receiving the first internal voltage signal driven by the first semiconductor device through a second pad portion electrically coupled to the first pad to apply the first internal voltage signal to a third electrode thereof, suitable for comparing a second internal voltage signal with the first internal voltage signal to drive the second internal voltage signal, and suitable for outputting the driven second internal voltage signal through a fourth electrode and a second through silicon via.
